(19) United States
(12) Patent Application Publication
(10) Pub. No.: US 2022/0004734 A1
(43) Pub. Date: Jan. 6, 2022

(54) FINGERPRINT RECOGNITION APPARATUS

(71) Applicant: Novatek Microelectronics Corp., Hsinchu (TW)

(72) Inventors: Ji-Ting Chen, Hsinchu County (TW); Wu-Wei Lin, Taoyuan City (TW); Cheng-Hsun Chan, Hsinchu County (TW)

(73) Assignee: Novatek Microelectronics Corp., Hsinchu (TW)

(21) Appl. No.: 17/475,367

(22) Filed: Sep. 15, 2021

Related U.S. Application Data
(63) Continuation-in-part of application No. 17/037,665, filed on Sep. 30, 2020.
(60) Provisional application No. 62/912,653, filed on Oct. 9, 2019.

(51) Int. Cl. G06K 9/00; H01L 27/146; G02F 1/1335; G02F 1/1333

(52) U.S. Cl. CPC G06K 9/0004; H01L 27/14623; H01L 27/14627; G02F 1/133526; G02F 1/133514; G02F 1/133512; G02F 1/13338; H01L 27/14678

(57) ABSTRACT

A fingerprint recognition apparatus including a frontplane, a backplane and a display medium layer is provided. The frontplane includes an upper substrate, a black matrix layer, a color filter layer, and a plurality of filtering elements. The black matrix layer is disposed on the upper substrate, and the color filter layer is disposed on the black matrix layer. The black matrix layer includes a plurality of pixel apertures and a plurality of first apertures. The filtering elements cover the first apertures and the filtering elements. The backplane includes a lower substrate and a sensor layer. The sensor layer includes a plurality of photo sensing elements. The photo sensing elements are configured to receive reflected lights from an object through the first apertures and the filtering elements. Areas of the photo sensing elements are overlapped with the first apertures in a longitudinal direction. The display medium layer is disposed between the frontplane and the backplane.

### CROSS-REFERENCE TO RELATED APPLICATION

This application is a continuation-in-part application of and claims the priority benefit of a prior application Ser. No. 17/037,665, filed on Sep. 30, 2020. The prior application Ser. No. 17/037,665 claims the priority benefits of U.S. provisional application Ser. No. 62/912,653, filed on Oct. 9, 2019. The entirety of the above-mentioned patent application is hereby incorporated by reference herein and made a part of this specification.

### BACKGROUND

### Technical Field

The disclosure relates to a fingerprint recognition apparatus, more specifically, to a fingerprint recognition apparatus capable of obtaining high contrast image.

### Description of Related Art

In the current in-display fingerprint technology, the layout of the photoelectric sensors is designed in a way that a pixel aperture of the black matrix in the display panel is also used as an aperture for the photoelectric sensor. Because of this structure, a large amount of returned light rays in various directions as scattered lights, reflection lights or refraction lights from the finger may transmits through the pixel aperture and hence each photoelectric sensor easily receives incident light rays having large angles of incidence, which carry a part of fingerprint image information not supposed to be received by the photoelectric sensor. Therefore, the contrast of the obtained image decreases so that the obtained image does not have the expected quality.

### SUMMARY

The disclosure is directed to a fingerprint recognition apparatus capable of obtaining high contrast image.

The disclosure provides a fingerprint recognition apparatus including a frontplane, a backplane and a display medium layer. The frontplane includes an upper substrate, a black matrix layer, a color filter layer, and a plurality of filtering elements. The black matrix layer is disposed on the upper substrate, and the color filter layer is disposed on the black matrix layer. The black matrix layer includes a plurality of pixel apertures and a plurality of first apertures. The filtering elements cover the first apertures. The backplane includes a lower substrate and a sensor layer. The sensor layer includes a plurality of photo sensing elements. The photo sensing elements are configured to receive returned lights from an object through the first apertures and the filtering elements. Areas of the photo sensing elements are overlapped with the first apertures in a longitudinal direction. The display medium layer is disposed between the frontplane and the backplane.

In an embodiment of the disclosure, the areas of the photo sensing elements are not overlapped with the pixel apertures of the black matrix layer in the longitudinal direction.

In an embodiment of the disclosure, the backplane further includes a first light shielding layer. The first light shielding layer includes a plurality of second apertures. The second apertures are configured to collimate the returned lights from the object. The first light shielding layer is one of a plurality of layers between the sensor layer and a display pixel electrode layer of the backplane.

In an embodiment of the disclosure, the first light shielding layer is disposed between the sensor layer and a bottom conductive layer of the backplane, and there is no other conductive layer positioned between the sensor layer and the bottom conductive layer.

In an embodiment of the disclosure, the first light shielding layer is disposed between two of a plurality of conductive layers from a bottom conductive layer to a top conductive layer of the backplane. The conductive layers are disposed between the sensor layer and a touch sensor layer, and the touch sensor layer also serves as a common electrode layer.

In an embodiment of the disclosure, the first light shielding layer is disposed between a top conductive layer of the backplane and a touch sensor layer, and the touch sensor layer also serves as a common electrode layer.

In an embodiment of the disclosure, the backplane further includes a second light shielding layer. The second light shielding layer includes a plurality of third apertures. The third apertures are configured to collimate the returned lights from the object.

In an embodiment of the disclosure, the frontplane further includes a second light shielding layer. The second light shielding layer is disposed between the upper substrate and the black matrix layer. The second light shielding layer includes a plurality of third apertures. The third apertures are configured to collimate the returned lights from the object.

In an embodiment of the disclosure, the color filter layer is extended to form the filtering elements covering the first apertures of the black matrix layer.

In an embodiment of the disclosure, the frontplane further includes a plurality of microlens covering the first apertures of the black matrix layer.

In an embodiment of the disclosure, a shape of each of the first apertures is the same as a shape of each of the second apertures.

In an embodiment of the disclosure, the backplane includes a device layer which is the same layer as the sensor layer.

In an embodiment of the disclosure, the backplane includes a device layer which is different from the sensor layer.

In an embodiment of the disclosure, the filtering elements are green color pass filters which allow green light to pass through and block lights of other colors which have wavelengths out of a wavelength range of the green light.

In an embodiment of the disclosure, the filtering elements are blue color pass filters which allow blue light to pass through and block lights of other colors which have wavelengths out of a wavelength range of the blue light.

In an embodiment of the disclosure, the filtering elements are pass filters which allow green light and blue light to pass through and block lights of other colors which have wavelengths out of a wavelength range of the green light and the blue light.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view of a display panel of a fingerprint recognition apparatus according to one embodiment of the disclosure.

FIG. 2A and FIG. 2B are schematic top views of a pixel of the display panel of the fingerprint recognition apparatus in FIG. 1.

FIG. 3A is a cross-sectional view of the pixel in FIGS. 2A-2B along an A-A′ direction according to an embodiment of the invention.

FIG. 3B is a cross-sectional view of the pixel in FIGS. 2A-2B along a B-B′ direction according to an embodiment of the invention.

FIG. 3C is a cross-sectional view of the pixel in FIGS. 2A-2B along an A-A′ direction according to another embodiment of the invention.

FIG. 3D is a cross-sectional view of the pixel in FIGS. 2A-2B along a B-B′ direction according to another embodiment of the invention.

FIG. 4 is a cross-sectional view of the display panel of FIG. 3C along an A-A′ direction.

FIG. 5A is a cross-sectional view of a pixel of a fingerprint recognition apparatus according to another embodiment of the disclosure.

FIG. 5B is a cross-sectional view of a pixel of a fingerprint recognition apparatus according to another embodiment of the disclosure.

FIG. 6A is a schematic top view of a pixel of the display panel of a fingerprint recognition apparatus according to another embodiment of the disclosure.

FIG. 6B is a schematic top view of a pixel of the display panel of a fingerprint recognition apparatus according to another embodiment of the disclosure.

FIGS. 7A and 7B are cross-sectional views of a pixel of a fingerprint recognition apparatus according to another embodiment of the disclosure.

FIGS. 7C and 7D are cross-sectional views of a pixel of a fingerprint recognition apparatus according to another embodiment of the disclosure.

FIGS. 8A and 8B are cross-sectional views of a pixel of a fingerprint recognition apparatus according to another embodiment of the disclosure.

FIGS. 9A, 9B, 9C and 9D are cross-sectional views of a pixel of a fingerprint recognition apparatus according to another embodiment of the disclosure.

FIG. 10 is a schematic top views of a pixel of the display panel of the fingerprint recognition apparatus according to an embodiment of the invention.

FIG. 11 is a cross-sectional view of the pixel in FIG. 10 along a B-B′ direction according to an embodiment of the invention.

### DESCRIPTION OF THE EMBODIMENTS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

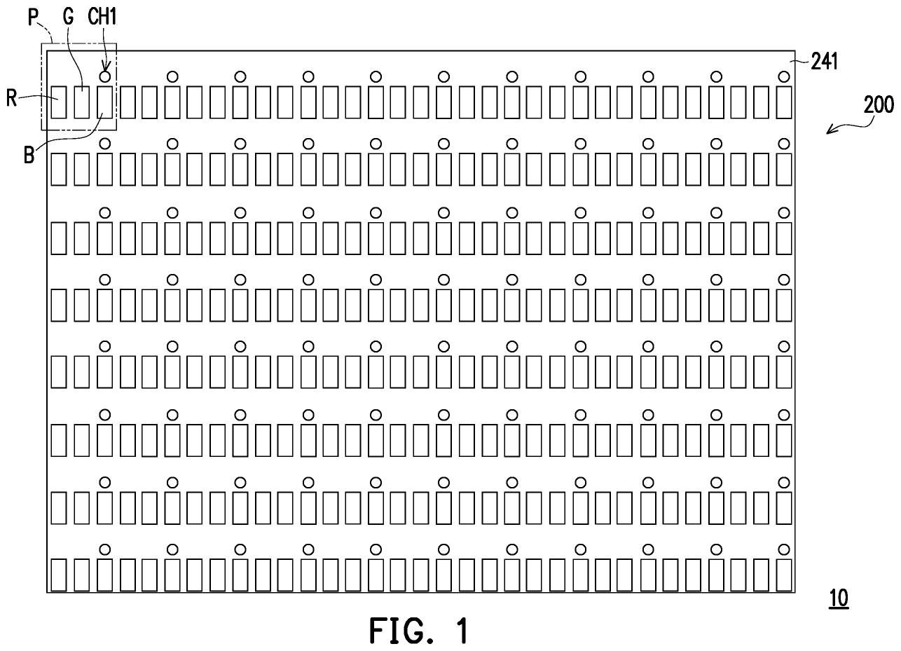

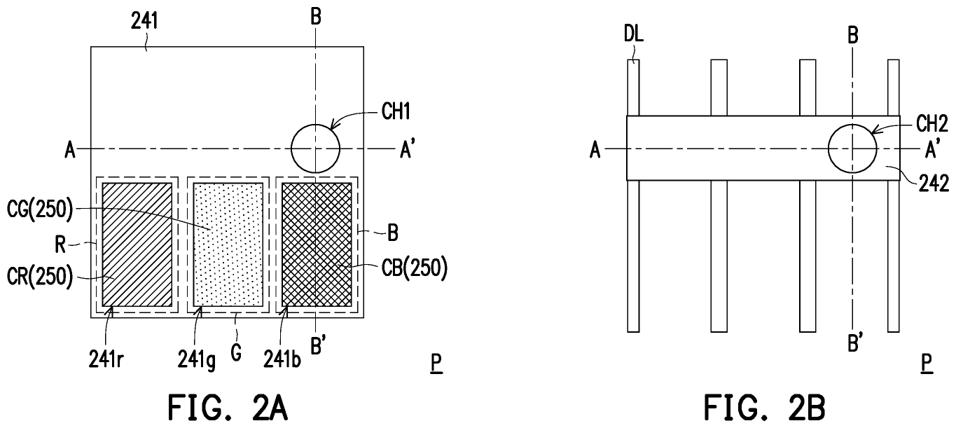

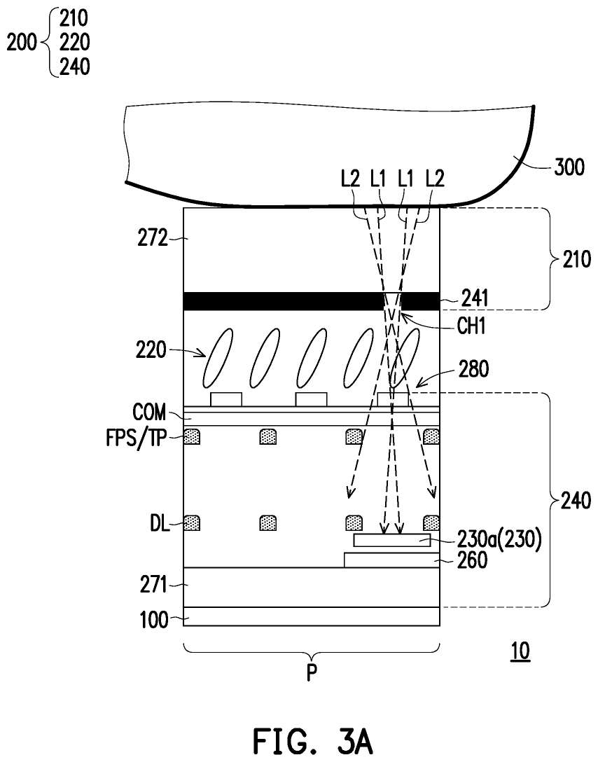

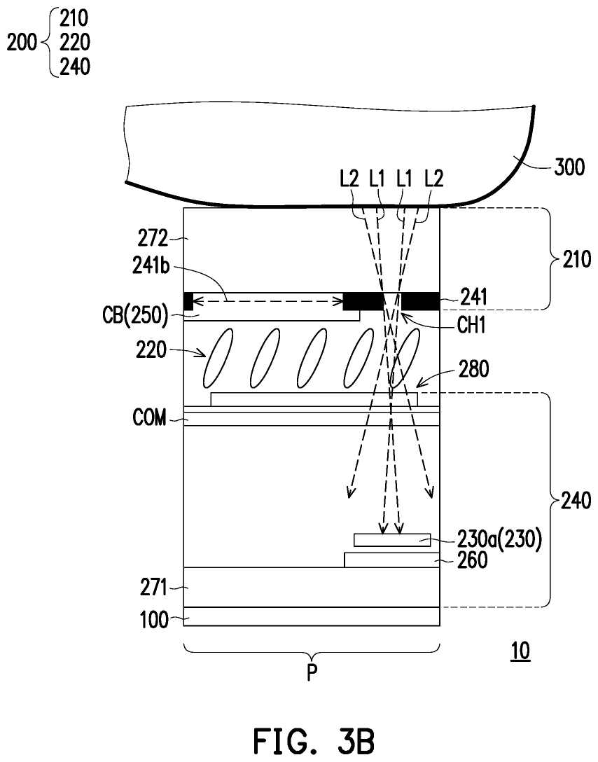

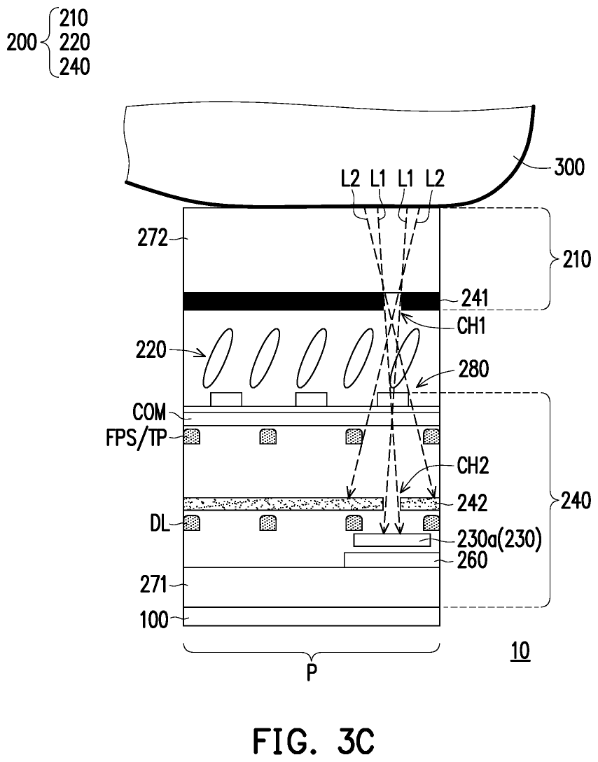

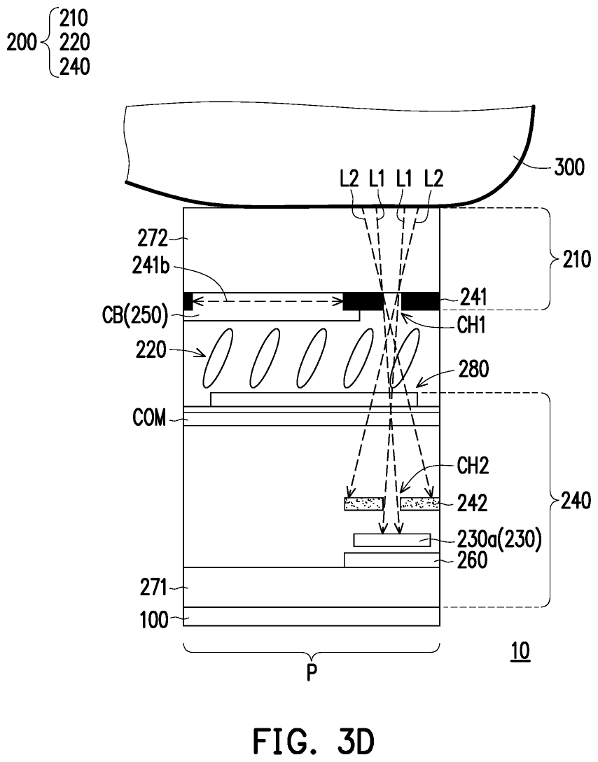

FIG. 1 is a schematic top view of a display panel of a fingerprint recognition apparatus according to one embodiment of the disclosure. FIG. 2A and FIG. 2B are schematic top views of a pixel of the display panel of the fingerprint recognition apparatus in FIG. 1. FIG. 3A is a cross-sectional view of the pixel in FIGS. 2A-2B along an A-A′ direction according to an embodiment of the invention. FIG. 3B is a cross-sectional view of the pixel in FIGS. 2A-2B along a line B-B′ direction according to an embodiment of the invention.

Referring to FIG. 1, FIGS. 2A-2B, and FIGS. 3A-3B simultaneously, a fingerprint recognition apparatus 10 includes a backlight module 100 and a display panel 200. The display panel 200 is disposed on the backlight module 100. The backlight module 100 is configured to emit light to the display panel 200. The fingerprint recognition apparatus 10 includes a frontplane 210, a backplane 240 and a display medium layer 220. The display medium layer 220 is disposed between the frontplane 210 and the backplane 240. In the present embodiment, the display medium layer 220 may be a liquid crystal layer, or an organic light emitting diode (OLED) layer, but the disclosure is not limited thereto.

The frontplane 210 includes an upper substrate 272, a black matrix layer 241 and a color filter layer 250. The black matrix layer 241 is disposed on a surface of the upper substrate 272 and under the upper substrate 272 in a longitudinal direction. The color filter layer 250 is disposed on a surface of the black matrix layer 241, and a part of the color filter layer 250 is under the black matrix layer 241 in the longitudinal direction. In the present embodiment, the black matrix layer 241 includes a plurality of pixel apertures 241r, 241g, and 241b and a plurality of first apertures CH1. In an embodiment, the color filter layer 250 may be disposed in the pixel apertures 241r, 241g, and 241b of the black matrix layer 241.

The backplane 240 includes a lower substrate 271 and a sensor layer 230. The sensor layer 230 includes a plurality of photo sensing elements 230a. Each photo sensing element 230a is configured to receive returned lights L1 from an object 300, which have small angles of incidence or is approximately normal to the photo sensing element 230a, through the first apertures CH1 of the black matrix layer 241. In the present embodiment, areas of the photo sensing elements 230a are overlapped with the first apertures CH1 in the longitudinal direction as shown in FIG. 3A and FIG. 3B. Benefit from a collimation effect of the first apertures CH1, returned lights having large angles, which are not limited to reflected lights or refracted lights from the object 300, may be prevented from being received by other photo sensing elements 230a adjacent to the photo sensing element 230a positioned below the first aperture CH1. In other words, the photo sensing element 230a positioned below the first aperture CH1 may not receive undesired the return lights of large angles, such that image contrast of a fingerprint image are enhanced. In addition, the areas of the photo sensing elements 230a are not overlapped with the pixel apertures 241r, 241g, or 241b of the black matrix layer 241 in the longitudinal direction.

In the present embodiment, the backplane 240 includes a device layer, i.e., a thin film transistor (TFT) layer, which is the same layer as the sensor layer 230, but the invention is not limited thereto. In an embodiment, the backplane 240 may include a device layer which includes a driver device and is different from the sensor layer 230.

In an embodiment, the display panel 200 may include a plurality of polarizers, such as a first polarizer and a second polarizer. The first polarizer is disposed on the backlight module 100 and under the backplane 240. The second polarizer is disposed on the front plane 210.

FIG. 3C is a cross-sectional view of the pixel in FIGS. 2A-2B along an A-A′ direction according to another embodiment of the invention. FIG. 3D is a cross-sectional view of the pixel in FIGS. 2A-2B along the B-B′ direction according to another embodiment of the invention. Referring to FIG. 1, FIGS. 2A-2B, and FIGS. 3C-3D simultaneously, the backplane 240 further includes a first light shielding layer 242 in the present embodiment. The first light shielding layer 242 is an intermediate layer between a top conductive layer and a bottom conductive layer of the backplane 240 and is disposed between the sensor layer 230 and the display medium layer 220. The first light shielding layer 242 includes a plurality of second apertures CH2, and the first apertures CH1 are respectively aligned with the second apertures CH2. The second apertures CH2 are configured to collimate the returned lights from the object 300 such that the reflect lights L2 with large incident angles which may result in interference to adjacent photo sensing elements are stopped by the first light shielding layer 242 and mostly the reflect lights L1 with small incident angles are received by the photo sensing element right under the corresponding first aperture CH1. The first light shielding layer 242 is one of a plurality of layers between the sensor layer 230 and a display pixel electrode layer 280 of the backplane 240.

For ease of description, only the black matrix layer 241 of the display panel 200 is shown in FIG. 1, and a cross-section of only a unit area of one pixel P is shown in FIGS. 2A and 2B. The display panel 200 includes a plurality of pixels P, and each of the pixels P includes a red subpixel R, a green subpixel G, and a blue subpixel B. As shown in FIG. 1 and FIG. 2A, in each pixel P of the display panel 200, the black matrix layer 241 includes three pixel apertures 241r, 241g, and 241b and one first apertures CH1. Further, in each pixel P, a red color filter CR, a green color filter CG, and a blue color filter CB of the color filter layer 250 are respectively disposed in the three pixel apertures 241r, 241g, and 241b in order to form the red sub-pixel R, the green sub-pixel G, and the blue sub-pixel B of each pixel P. In each unit area of the pixel P of the present embodiment, the first apertures CH1 is located beside the pixel aperture 241b of the blue sub-pixel B, and the pixel aperture 241b is closer to the first apertures CH1 than the pixel aperture 241r and the pixel aperture 241g. In other words, the first apertures CH1 is closest to the pixel aperture 241b of the blue sub-pixel B. However, the disclosure is not limited thereto, in other embodiments, the first apertures CH1 may be closest to the pixel aperture 241r of the green sub-pixel G, may be closest to the pixel aperture 241r of the red sub-pixel R, or may be located at any position in each unit area of the pixel P.

As shown in FIG. 2B, in each unit area of the pixel P, the first light shielding layer 242 includes one second apertures CH2, and the first light shielding layer 242 is located above a conductive layer where data lines DL of the display panel 200 are formed. The first apertures CH1 and the second apertures CH2 are aligned with each other. The alignment of the first aperture CH1 and the second aperture CH2 means the center of the first aperture CH1 and the center of the second aperture CH2 share the same center axis, or means the center of one aperture is very close to the center axis of the other aperture. The first apertures CH1 may be called as the first collimation hole, and the second apertures CH2 may be called as the second collimation hole. In the present embodiment, the shapes of the first apertures CH1 and the second apertures CH2 are the same. In the present embodiment, the shapes of the first apertures CH1 and the second apertures CH2 are circular shapes, but the disclosure is not limited thereto. Additionally, the size/diameter of the first apertures CH1 may be greater than, equal to, or smaller than the size/diameter of the second apertures CH2.

In the present embodiment, the first light shielding layer 242 is disposed between a conductive layer where the data lines DL are formed and another conductive layer where the fingerprint sensing line and/or touch sensing lines (denoted as FPS/TP) are formed. The conductive layer of data lines DL and the conductive layer of the sensing lines FPS/TP are disposed between the sensor layer 230 and a touch sensor layer, and the touch sensor layer also serves as a common electrode layer COM.

To be specific, as shown in FIG. 3C and FIG. 3D, the display panel 200 further includes a third light shielding layer 260, a display pixel layer 280, a touch sensor layer serving as a common electrode COM, and a conductive layer where the sensing lines FPS/TP are. The third light shielding layer 260 is formed on the lower substrate 271 and is located between the lower substrate 271 and the sensor layer 230. The conductive layer of data lines DL is located between the sensor layer 230 and the first light shielding layer 242. The conductive layer of the sensing lines FPS/TP is disposed above the first light shielding layer 242 and is disposed between the first light shielding layer 242 and the common electrode COM. In addition, the common electrode COM is located above the conductive layer of the sensing lines FPS/TP and is located between the conductive layer of the sensing lines FPS/TP and the display pixel layer 280. The display pixel layer 280 is located between the display medium layer 220 and the common electrode COM. In addition, two polarizers (not shown) are respectively attached on the top surface and the bottom surface of the display panel 200.

It should be noted here, as shown in FIG. 2A and FIG. 3B, the first apertures CH1 and the second apertures CH2 do not overlap with the pixel apertures 241r, 241g, and 241b in each unit area of the pixel P of the fingerprint recognition apparatus 10.

Further, in the present embodiment, the third light shielding layer 260 is an under shading layer which blocks the light (not shown) directly emitted from the backlight module 100. That is to say, the light emitted from the backlight module 100 cannot be directly transmitted to reach the sensor layer 230. The light emitted from the backlight module 100 passes through the pixel apertures 241r, 241g, and 241b, reaches to an object 300 (such as a finger) in contact with the fingerprint recognition apparatus 10 and are returned from the object 300. Then the returned light carrying information of an image of the object 300 is transmitted toward the sensor layer 230.

In the present embodiment, since the first apertures CH1 is aligned with the second apertures CH2, the first apertures CH1 and the second apertures CH2 expose a photo sensing elements 230a of the sensor layer 230. Therefore, with respect to each photo sensing element, a part of the returned light is able to reach the photo sensing element 230a and other part of the returned lights which may interfere adjacent photo sensing elements can be blocked by the first light shielding layer 242. To be more specific, as shown in FIGS. 3C and 3D, the returned light ray L1 may be reflected/refracted from an area, which is aligned or corresponding to the first apertures CH1 and the second apertures CH2, of the object 300, in a direction substantially parallel to the vertical direction, so the emitted light ray L1 can pass through the first apertures CH1 and the second apertures CH2 and reach the photo sensing elements 230a of the sensor layer 230. However, the returned light ray L2 in a direction of a large angle of reflection or refraction (or, in view of an adjacent photo sensing element, a large angle of incidence) is blocked by at least one of the black matrix layer 241 and the first light shielding layer 242 and cannot reach the adjacent photo sensing elements 230a of the sensor layer 230. That is to say, the emitted light is approximately collimated before reaching the photo sensing elements 230a of the sensor layer 230. In the disclosure, it is preferred that the second apertures CH2 is close to the photo sensing elements 230a as much as possible and the second apertures CH2 is far from the first apertures CH1 as much as possible. In other words, the distance between the first light shielding layer 242 and the sensor layer 230 is as short as possible, and the distance between the first light shielding layer 242 and the black matrix layer 241 is as long as possible.

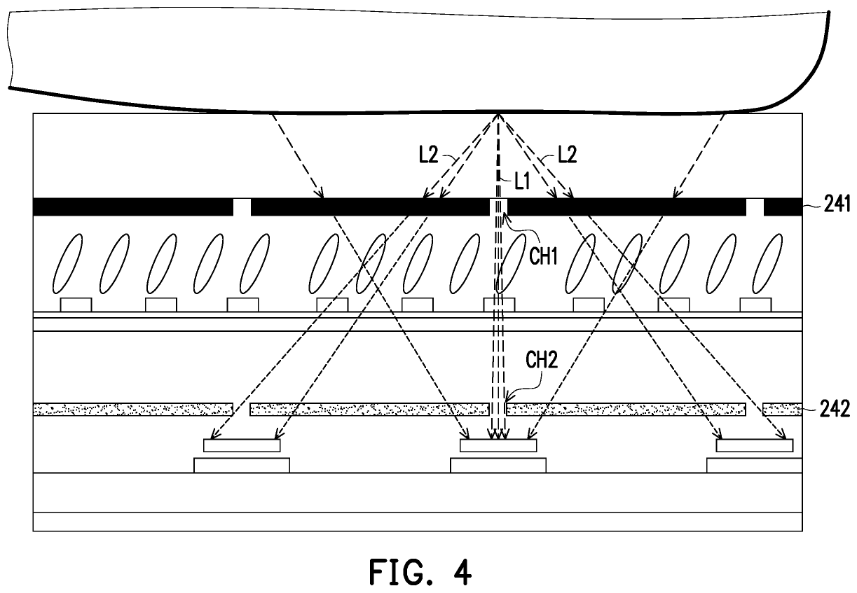

FIG. 4 is a cross-sectional view of the display panel of FIG. 3C along an A-A′ direction. FIG. 4 illustrates the collimation effect brought by the first apertures CH1 and the second apertures CH2.

In the present embodiment, because of the manufacturing process, the black matrix layer 241 may be made of a metal material, an organic material, or a colored coating material, and the first light shielding layer 242 may be made of metal material. Further, the black matrix layer 241 is the black matrix of the display panel 200. In other words, the first apertures CH1 are formed on the black matrix of the display panel 200.

Furthermore, in the disclosure, the photo sensing elements 230a may be a photoelectric sensor. According to the characteristics of the photoelectric sensor, filters can be added to improve signal to noise ratio (SNR). The details will be provided hereinafter.

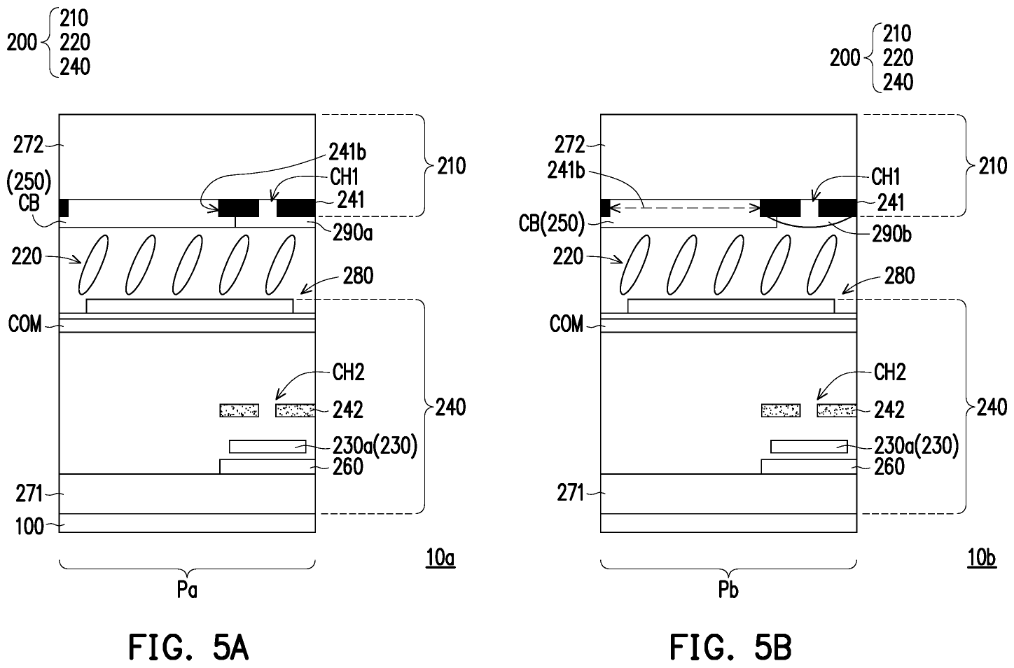

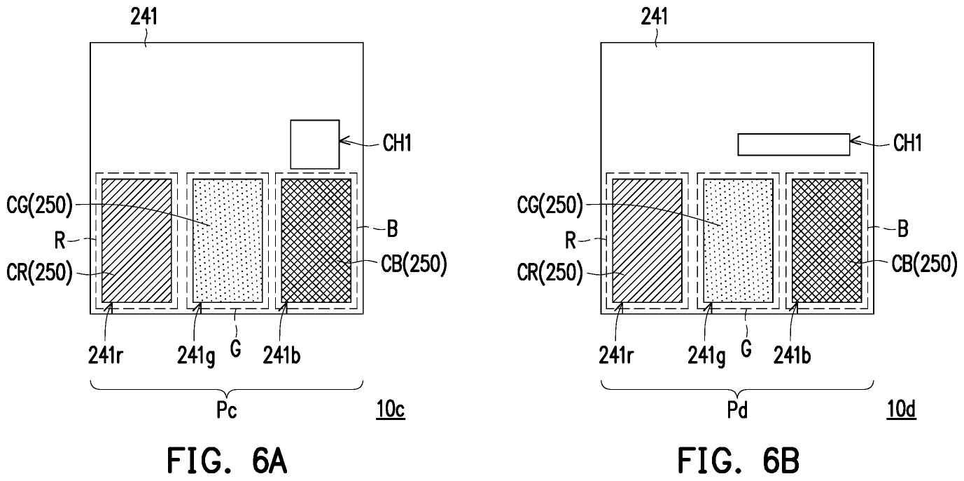

FIG. 5A is a cross-sectional view of a pixel of a fingerprint recognition apparatus according to another embodiment of the disclosure. A pixel Pa in the fingerprint recognition apparatus 10a shown in FIG. 5A is similar to the pixel P in the fingerprint recognition apparatus 10, only the differences are described hereinafter. In the pixel Pa of the fingerprint recognition apparatus 10a shown in FIG. 5A, the sensors 230a of the sensor layer 230 are adapted for sensing infrared lights. The frontplane 210 further includes a plurality of filtering elements 290a covering the first apertures CH1 of the black matrix layer 241. For example, in the fingerprint recognition apparatus 10a, the filtering elements 290a may be the infrared pass filter material or the infrared pass filter which allows the infrared light to pass through and filter out the visible light to prevent the sensors 230a from being interfered by visible lights. However, the disclosure is not limited thereto. In other embodiments, the sensors 230a of the sensor layer 230 are adapted for sensing visible light. The filtering elements 290a may be the infrared filter material or the infrared filter that passes only visible lights and filter out the infrared light to prevent the sensors 230a from being interfered by infrared light. Therefore, the effect of infrared light is prevented and the signal to noise ratio is increased.

FIG. 5B is a cross-sectional view of a pixel of a fingerprint recognition apparatus according to another embodiment of the disclosure. A pixel Pb in the fingerprint recognition apparatus 10b shown in FIG. 5B is similar to the pixel P in the fingerprint recognition apparatus 10, only the differences are described hereinafter. In the pixel Pb of the fingerprint recognition apparatus 10b shown in FIG. 5B, the sensors 230a of the sensor layer 230 are the visible light sensors that measures and detects visible light. The frontplane 210 further includes a plurality of microlens 290b covering the first apertures CH1 of the black matrix layer 241. The first aperture CH1 is covered by a micro-lens 290b that is adapted for guiding the visible light to the photo sensing elements 230a, so as to increase the signal to noise ratio.

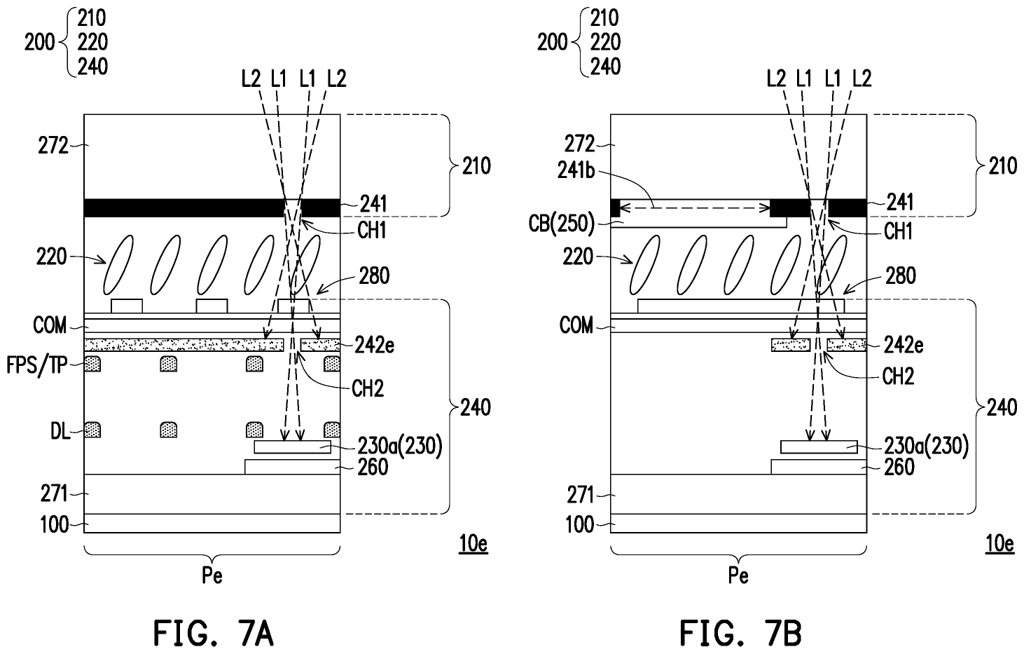

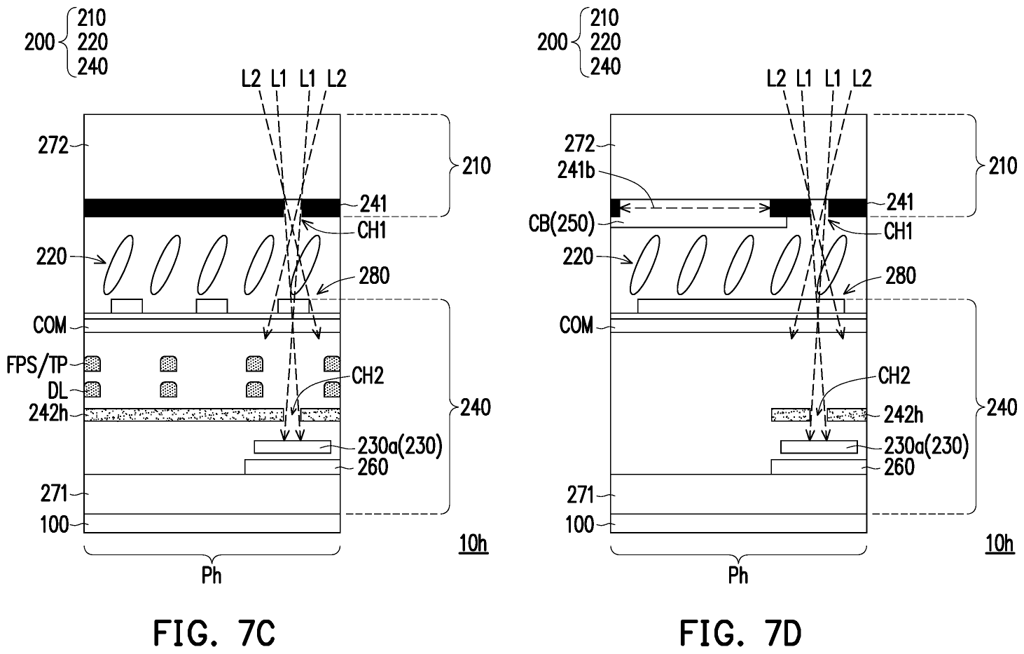

FIG. 6A is a schematic top view of a pixel of the display panel of a fingerprint recognition apparatus according to another embodiment of the disclosure. A pixel Pc in the fingerprint recognition apparatus 10c shown in FIG. 6A is similar to the pixel P in the fingerprint recognition apparatus 10, only the differences are described hereinafter. In the pixel Pc of the fingerprint recognition apparatus 10c shown in FIG. 6A, the shape of the first apertures CH1 is a square shape instead of a circular shape. In addition, the shape of the second apertures CH2 is the same as the shape of the first apertures CH1.

FIG. 6B is a schematic top view of a pixel of the display panel of a fingerprint recognition apparatus according to another embodiment of the disclosure. A pixel Pd in the fingerprint recognition apparatus 10d shown in FIG. 6B is similar to the pixel P in the fingerprint recognition apparatus 10, only the differences are described hereinafter. In the pixel Pd of the fingerprint recognition apparatus 10d shown in FIG. 6B, the shape of the first apertures CH1 is a rectangular shape instead of a circular shape. In addition, the shape of the second apertures CH2 is the same as the shape of the first apertures CH1. In the present disclosure, the width of the first aperture CH1 or the second aperture CH2 is not limited to be smaller than the width of a subpixel.

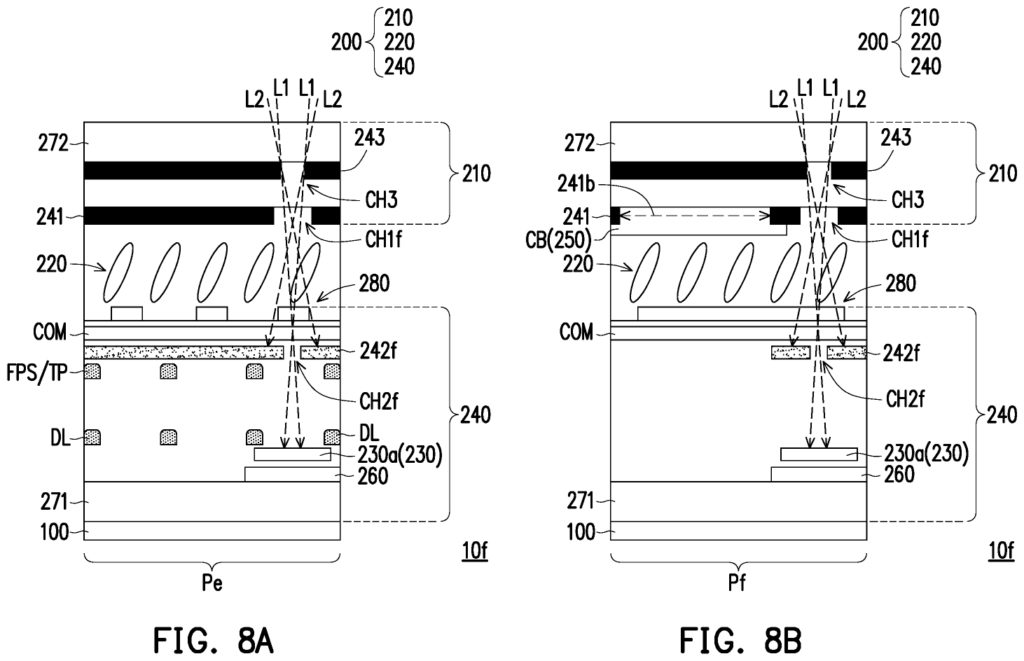

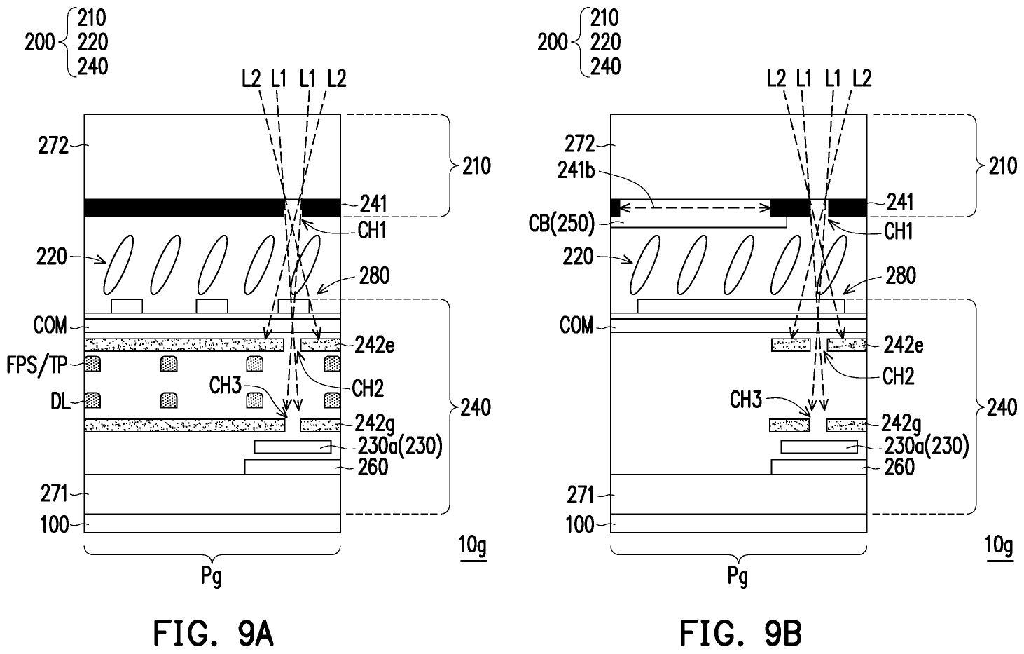

FIGS. 7A and 7B are cross-sectional views of a pixel of a fingerprint recognition apparatus according to another embodiment of the disclosure. A pixel Pe in the fingerprint recognition apparatus 10e shown in FIGS. 7A and 7B is similar to the pixel P of the fingerprint recognition apparatus 10 shown in FIGS. 3C and 3D, only the differences are described hereinafter. In the pixel Pe of the present embodiment, a first light shielding layer 242e is located between the common electrode COM (the touch sensor layer) and the conductive layer of sensing lines FPS/TP.

FIGS. 7C and 7D are cross-sectional views of a pixel of a fingerprint recognition apparatus according to another embodiment of the disclosure. A pixel Ph in the fingerprint recognition apparatus 10h shown in FIGS. 7C and 7D is similar to the pixel P of the fingerprint recognition apparatus 10 shown in FIGS. 3C and 3D, only the differences are described hereinafter. In the pixel Ph of the present embodiment, the first light shielding layer 242h is disposed between the sensor layer 230 and the conductive layer of the data line DL (the bottom conductive layer of the backplane 240), and there is no other conductive layer positioned between the sensor layer 230 and the bottom conductive layer DL.

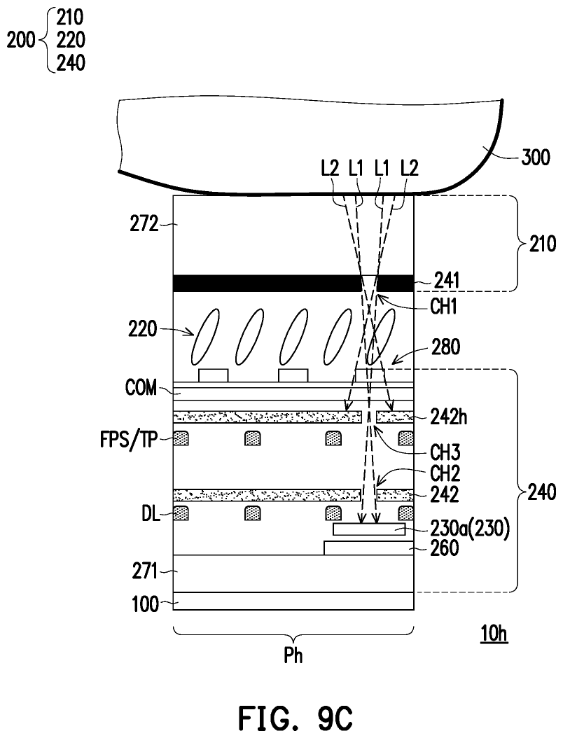

FIGS. 8A and 8B are cross-sectional views of a pixel of a fingerprint recognition apparatus according to another embodiment of the disclosure. A pixel Pf in the fingerprint recognition apparatus 10f shown in FIGS. 8A and 8B is similar to the pixel Pe of the fingerprint recognition apparatus 10e shown in FIGS. 7A and 7B, only the differences are described hereinafter. The frontplane 210 further includes a second light shielding layer 243. The second light shielding layer 243 is disposed between the upper substrate 272 and the black matrix layer 241. The second light shielding layer 243 includes a plurality of third apertures CH3. The third apertures CH3 are configured to collimate the returned lights from the object 300. In another embodiment using two layers of collimation apertures (CH1 and CH3) in the frontplane 210, the position of the first light shielding layer 242 may be referred to the positions depicted in FIGS. 3C-3D and FIGS. 7C-7D.

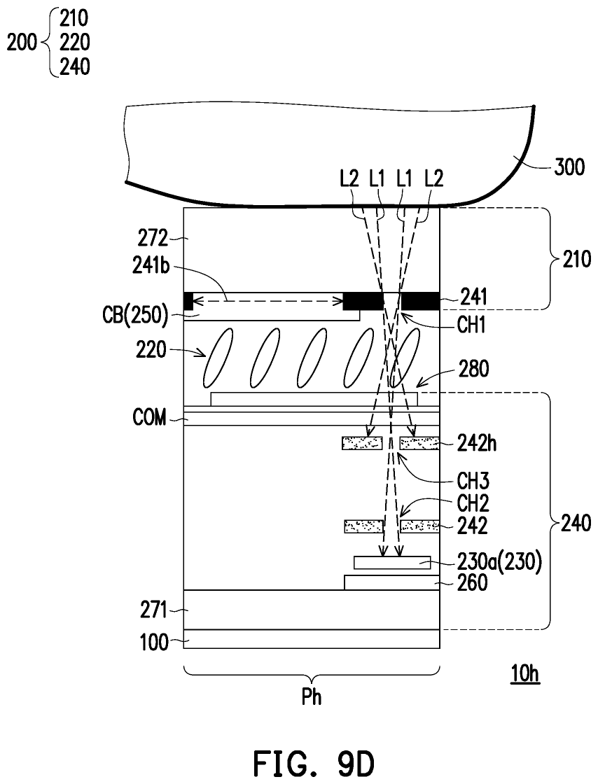

In an embodiment, the backplane 240 may further include a second light shielding layer including a plurality of third apertures, in addition to the first light shielding layer including the first apertures CH1. The examples of the second light shielding layer are depicted in FIGS. 9A-9D.

FIGS. 9A, 9B, 9C and 9D are cross-sectional views of a pixel of a fingerprint recognition apparatus according to another embodiment of the disclosure. A pixel Pg in the fingerprint recognition apparatus 10g shown in FIGS. 9A and 9B is similar to the pixel Pe of the fingerprint recognition apparatus 10e shown in FIGS. 7A and 7B, only the differences are described hereinafter. In the fingerprint recognition apparatus 10g of the present embodiment, the first light shielding layer 242e is located between the conductive layer of sensing lines FPS/TP and the common electrode COM, and a second light shielding layer 242g is located between the conductive layer of data line DL and the sensor layer 230. The first light shielding layer 242e includes the second apertures CH2, and the second light shielding layer 242g includes a plurality of third apertures CH3. The first apertures CH1, the second apertures CH2 and the third apertures CH3 are aligned with each other to expose the photo sensing elements 230a of the sensor layer 230.

A pixel Ph in the fingerprint recognition apparatus 10h shown in FIGS. 9C and 9D is similar to the pixel Pe of the fingerprint recognition apparatus 10e shown in FIGS. 3C and 3D, only the differences are described hereinafter. In the fingerprint recognition apparatus 10h of the present embodiment, the first light shielding layer 242 is located between the conductive layer of sensing lines FPS/TP and the conductive layer of data line DL, and a second light shielding layer 242h is located between the conductive layer of sensing lines FPS/TP and the common electrode layer COM. The first light shielding layer 242 includes the second apertures CH2, and the second light shielding layer 242h includes a plurality of third apertures CH3.

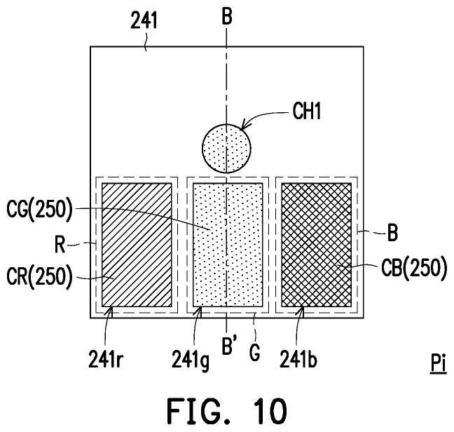

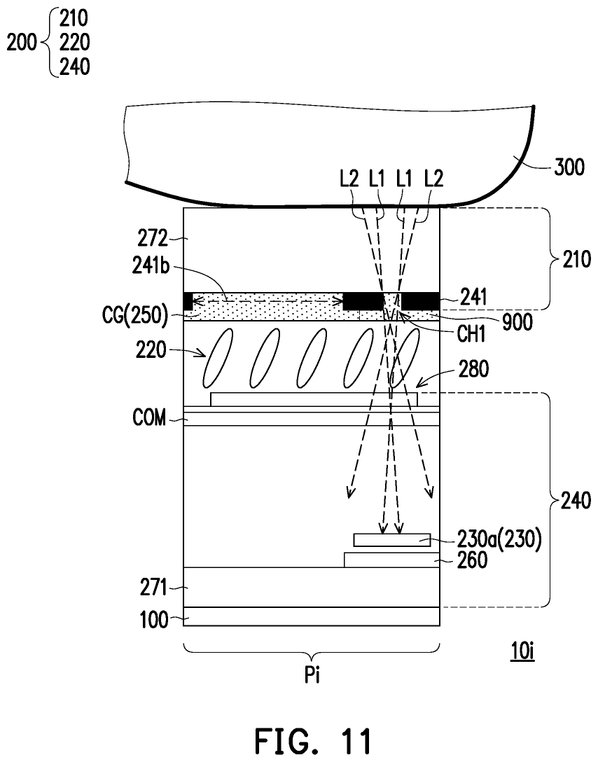

Visible light or non-visible light of wavelength higher than (approximate) 600 nm, which is visible red light or infrared light, has a high transmittance. The un-desired high-transmittance light in the environment may also transmit into the finger when a user uses a fingerprint recognition apparatus such as a mobile phone or a tablet computer, which results in negative influences to the fingerprint sensing. For example, fingerprint sensing signals may get saturated easily. When the fingerprint recognition apparatus is operated in an environment with strong ambient light, such as strong sunlight at the outdoors, the high-transmittance light included in the strong ambient light may influence the operation of the fingerprint sensing and consequently, the quality of a resultant fingerprint image is degraded. To minimize this influence, the present disclosure provides embodiments such as illustrated in FIG. 10 and FIG. 11. FIG. 10 is a schematic top views of a pixel of the display panel of the fingerprint recognition apparatus according to an embodiment of the invention. FIG. 11 is a cross-sectional view of the pixel in FIG. 10 along a B-B′ direction according to an embodiment of the invention. Referring to FIG. 10 and FIG. 11, a pixel Pi in the fingerprint recognition apparatus 10i shown in FIG. 10 and FIG. 11 is similar to the pixel P in the fingerprint recognition apparatus 10 shown in FIG. 2A and FIG. 3B, only the differences are described hereinafter.

In the present embodiment, the frontplane 210 further includes a plurality of filtering elements 900. The filtering elements 900 cover the first apertures CH1 of the black matrix layer 241. The filtering elements 900 are, for example, green color pass filters which allow green light to pass through and block lights of other colors which have wavelengths out of a wavelength range of the green light. Therefore, the photo sensing elements 230a receive reflected lights L1 from the object 300 through the first apertures CH1 and the filtering elements 900. The filtering elements 900 acted as green color pass filters may be made of material same as the green color filters CG of the color filter layer 250, or may be made of material different from the green color filters CG of the color filter layer 250. In the case of the same material, the green color filters CG of the color filter layer 250 may be extended to form the filtering elements 900. As a result, infrared lights and red lights included in the ambient light cannot pass through the filtering elements 900 and cannot be received by the photo sensing elements 230a since the filtering elements 900 are green color pass filters.

In another embodiment different from FIG. 10, the filtering elements covering the first apertures CH1 of the black matrix layer 241 may be blue color pass filters, which allows blue light to pass through and block lights of other colors which have wavelengths out of a wavelength range of the blue light. The filtering elements acted as blue color pass filters may be made of material same as the blue color filters CB of the color filter layer 250, or may be made of material different from the blue color filters CB of the color filter layer 250. In the case of the same material, the blue color filters CB of the color filter layer 250 may be extended to form the filtering elements. As a result, infrared lights and red lights included in the ambient light cannot pass through the filtering elements and cannot be received by the photo sensing elements 230a since the filtering elements are blue color pass filters.

In another embodiment, the filtering elements covering the first apertures CH1 of the black matrix layer 241 may be pass filters which allow green light and blue light to pass through and block lights of other colors which have wavelengths out of a wavelength range of the green light and the blue light. In such a case the filtering elements are not formed by extended green color filters CG or extended blue color filters CB of the color filter layer 250. As a result, infrared lights and red lights included in the ambient light cannot pass through the filtering elements and cannot be received by the photo sensing elements 230a since the filtering elements are green and blue color pass filters.

In the present embodiment, since the filtering elements 900 are green color pass filters which allow green light to pass through, infrared lights and red lights from an environment cannot pass through the first apertures CH1. Therefore, the photo sensing elements 230a are not affected by the infrared lights and the red lights from the environment.

In summary, in the embodiments of the disclosure, since the first apertures of the black matrix layer are respectively aligned with the second apertures of the first light shielding layer to expose the sensors of the sensor layer and act as a collimator in the fingerprint recognition apparatus, only the returned light rays substantially parallel to the alignment direction of the first aperture and the second aperture can pass through the first aperture and the second aperture and reach the sensor of the sensor layer. In addition, the third light shielding layer blocks the light (not shown) directly emitted from the backlight module, so that the light emitted from the backlight module cannot be directly transmitted to reach the sensor layer. Therefore, the light interference is prevented and the image obtained by the fingerprint recognition apparatus has a high contrast.

Further, the first apertures are filled by filter materials or covered by micro-lens according to the characteristics of the sensors, as to improve the signal to noise ratio.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A fingerprint recognition apparatus, comprising:
a frontplane, comprising an upper substrate, a black matrix layer disposed on the upper substrate, and a color filter layer disposed on the black matrix layer, and a plurality of filtering elements, wherein the black matrix layer comprises a plurality of pixel apertures and a plurality of first apertures, and the filtering elements cover the first apertures of the black matrix layer;
a backplane, comprising a lower substrate and a sensor layer comprising a plurality of photo sensing elements, wherein the photo sensing elements are configured to receive reflected lights from an object through the first apertures and the filtering elements, and areas of the photo sensing elements are overlapped with the first apertures in a longitudinal direction; and
a display medium layer, disposed between the frontplane and the backplane.

2. The fingerprint recognition apparatus of claim 1, wherein the areas of the photo sensing elements are not overlapped with the pixel apertures of the black matrix layer in the longitudinal direction.

3. The fingerprint recognition apparatus of claim 1, wherein the backplane further comprises:
a first light shielding layer, comprising a plurality of second apertures, wherein the second apertures are configured to collimate the reflected lights from the object, and the first light shielding layer is one of a plurality of layers between the sensor layer and a display pixel electrode layer of the backplane.

4. The fingerprint recognition apparatus of claim 3, wherein the first light shielding layer is disposed between the sensor layer and a bottom conductive layer of the backplane, and there is no other conductive layer positioned between the sensor layer and the bottom conductive layer.

5. The fingerprint recognition apparatus of claim 3,
wherein the first light shielding layer is disposed between two of a plurality of conductive layers from a bottom conductive layer to a top conductive layer of the backplane,
wherein the conductive layers are disposed between the sensor layer and a touch sensor layer, and the touch sensor layer also serves as a common electrode layer.

6. The fingerprint recognition apparatus of claim 3, wherein the first light shielding layer is disposed between a top conductive layer of the backplane and a touch sensor layer, and the touch sensor layer also serves as a common electrode layer.

7. The fingerprint recognition apparatus of claim 3, wherein the backplane further comprises:
a second light shielding layer, comprising a plurality of third apertures, wherein the third apertures are configured to collimate the reflected lights from the object.

8. The fingerprint recognition apparatus of claim 3, wherein the frontplane further comprises:
a second light shielding layer, disposed between the upper substrate and the black matrix layer and comprising a plurality of third apertures, wherein the third apertures are configured to collimate the reflected lights from the object.

9. The fingerprint recognition apparatus according to claim 1, wherein the color filter layer is extended to form the filtering elements covering the first apertures of the black matrix layer.

10. The fingerprint recognition apparatus according to claim 1, wherein the frontplane further comprises a plurality of microlens covering the first apertures of the black matrix layer.

11. The fingerprint recognition apparatus according to claim 3, wherein a shape of each of the first apertures is the same as a shape of each of the second apertures.

12. The fingerprint recognition apparatus according to claim 1, wherein the backplane comprises a device layer which is the same layer as the sensor layer.

13. The fingerprint recognition apparatus according to claim 1, wherein the backplane comprises a device layer which is different from the sensor layer.

14. The fingerprint recognition apparatus according to claim 1, wherein the filtering elements are green color pass filters which allow green light to pass through and block lights of other colors which have wavelengths out of a wavelength range of the green light.

15. The fingerprint recognition apparatus according to claim 1, wherein the filtering elements are pass filters which allow green light and blue light to pass through and block lights of other colors which have wavelengths out of a wavelength range of the green light and the blue light.

16. The fingerprint recognition apparatus according to claim 1, wherein the filtering elements are pass filters which allow blue light to pass through and block lights of other colors which have wavelengths out of a wavelength range of the blue light.
